(19) United States
(12) Patent Application Publication
(10) Pub. No.: US 2011/0079834 A1
(43) Pub. Date: Apr. 7, 2011

(54) SEMICONDUCTOR INTEGRATED CIRCUIT DEVICE

(75) Inventors: Masayuki YANAGISAWA, Kanagawa (JP); Hiroshi Furuta, Kanagawa (JP); Hiroyasu Kitajima, Kanagawa (JP); Katsuya Izumi, Kanagawa (JP)

(73) Assignee: Renesas Electronics Corporation, Kanagawa (JP)

(21) Appl. No.: 12/896,233

(22) Filed: Oct. 1, 2010

(30) Foreign Application Priority Data
Oct. 2, 2009 (JP) 2009-230931

(51) Int. Cl. H01L 29/94

(52) U.S. Cl. 257/296; 257/E29.345

(57) ABSTRACT

A semiconductor integrated circuit device has: a MISFET having source/drain diffusion layers; first plugs respectively connected to the source/drain diffusion layers; a first interconnection connected to one of the source/drain diffusion layers through the first plug; a second plug electrically connected to the other Of the source/drain diffusion layers through the first plug; a second interconnection connected to the second plug; and a capacitor electrode located above a gate electrode of the MISFET. The first interconnection is formed not above the lower capacitor electrode, while the second interconnection is formed above the upper capacitor electrode. A plug connecting the first interconnection and another interconnection is not provided at an upper location of the one of the source/drain diffusion layers. The first interconnection is not provided at an upper location of the other of the source/drain diffusion layers.

### INCORPORATION BY REFERENCE

This application is based upon and claims the benefit of priority from Japanese patent application No. 2009-230931, filed on Oct. 2, 2009, the disclosure of which is incorporated herein in its entirety by reference.

### BACKGROUND OF THE INVENTION

1. Field of the Invention

The present invention relates to a semiconductor integrated circuit device. In particular, the present invention relates to MISFET source/drain electrodes and interconnections in a memory product such as a DRAM (Dynamic Random Access Memory) and a FeRAM (Ferroelectric Random Access Memory) having a stack type capacitor and a MRAM (Magnetic Random. Access Memory) having a data retention section and a memory embedded logic product provided with the memory.

2. Description of Related Art

An LSI memory such as a DRAM (Dynamic Random Access Memory), an FeRAM (Ferroelectric Random Access Memory) and an MRAM (Magnetic Random Access Memory) is known (for example, refer to Patent Documents 1 to 3 listed below). The memory device such as the DRAM and the FeRAM has a data retention section composed of a capacitor element. The memory device such as the MRAM has a data retention section composed of an MTJ (Magnetic Tunnel Junction) element.

Such a memory device is also installed in a memory embedded logic IC having a plurality of MISFETs (Metal Insulator Semiconductor Field Effect Transistors). The memory embedded logic IC has a data memory region (may be hereinafter referred to as a memory cell section) such as a memory cell array and a logic circuit section (may be hereinafter referred to as a logic circuit section). The memory cell section and the logic circuit section are different in “height” above a surface of a semiconductor substrate. Thus, there exists a “difference in height” between the memory cell section and the logic circuit section.

Regarding a source/drain electrode of the MISFET of the memory embedded logic. IC, a diffusion layer is connected to an upper layer interconnection through a contact (plug). In many cases, the contact (plug) connecting between the diffusion layer and the upper layer interconnection in the memory embedded logic IC is longer than a plug in an IC having no memory cell section. This causes a problem that an aspect ratio of the contact (plug) becomes large in the case of the memory embedded logic IC.

Moreover, a size of the MISFET has been decreased with miniaturization of the semiconductor integrated circuit device. Therefore, in the case where the long plug is required for connecting between the source/drain diffusion layer and the upper layer interconnection, a resistance value of the plug is increased. Furthermore, parasitic capacitance between the plugs respectively connected to the source diffusion layer and the drain diffusion layer is increased.

The Patent Document 1 (Japanese Patent Publication JP-H09-275193) discloses a technique in which a source/drain electrode of a MISFET is connected to an interconnect layer above a DRAM cell through an interconnect layer of the same process as a capacitor lower electrode of the DRAM cell. The Patent Document 2 (Japanese Patent Publication JP-2008-251763) discloses a structure in which an assist interconnect layer is provided between a capacitor lower electrode layer of a DRAM and a bit line electrode layer. The Patent Document 3 (Japanese Patent Publication JP-2006-295130) discloses a technique in which both of source/drain electrodes of a MISFET are connected to an interconnect layer of the same process as a bit line electrode of a DRAM cell, and one of the source/drain electrodes is connected to an interconnect layer above the DRAM cell.

These Patent Documents disclose techniques regarding the contact (plug) that electrically connects between the source/drain diffusion layer of the MISFET and the upper layer interconnection, reduction of the aspect ratio of a contact hole, reduction of the resistance value of the contact plug, and improvement in electrical connection between the metal plug and a base layer.

Next, a method of manufacturing a DRAM embedded logic IC product (may be hereinafter referred to as an eDRAM product) having a memory cell section and a peripheral MISFET region (logic circuit section) according to the related technique will be described below. It should he noted that the related technique described below is basically the same as the techniques described in the Patent Documents 1, 2 and 3. FIG. 1 is a plan view showing the memory cell section and the peripheral MISFET region (logic circuit section) according to the related technique. FIG, 2 shows cross-sectional structures taken along a line A-A′ and a line B-B′ in FIG. 1.

The method of manufacturing the eDRAM product having the memory cell section and the peripheral MISFET region (logic circuit section) according to the related technique is as follows. A device isolation film 102 and a device formation region (diffusion layer region) 103 are formed at predetermined locations of a first conductivity type semiconductor substrate 101. Then, a gate electrode 105 is formed on a channel region of a MISFET through a gate insulating film 104.

A side wall insulating film 106 is so formed as to cover around the gate electrode 105. Next, impurity ions are doped and then heat treatment is performed to form second conductivity type semiconductor regions 107 as source/drain diffusion layers in the device formation region 103. Then, a first interlayer insulating film 108 is formed on the entire surface. First contacts 109 are formed at predetermined locations in the first interlayer insulating film 108. Then, a bit line 110 connected to the first contact 109 is formed,

A second interlayer insulating film 111 is formed on the entire surface. Then, second contacts 112 are so formed at corresponding locations of the first contacts 109 as to be directly connected to the respective first contacts 109. A third interlayer insulating film 113 is formed on the entire surface. A first capacitor electrode 114 of a memory cell is formed at a predetermined location in the third interlayer insulating film 113. After that, a capacitor insulating film 115 and a metal layer are blanket deposited and then a second capacitor electrode 116 is formed.

Furthermore, a fourth interlayer insulating film 117 is formed on the entire surface. Then, third contacts 118 are so formed at corresponding locations of the second contacts 112 as to be directly connected to the respective second contacts 112. An upper layer metal interconnection 119 connected to the third contact 118 is formed.

FIG. 3 is a plan view showing the peripheral MISFET region according to the related technique in a case where the number of gate electrodes is four and the source electrodes are connected to a first conductivity type semiconductor region 120 as a substrate potential diffusion layer. FIG. 4 is a cross-sectional view taken along a line C-C′ in FIG. 3. The first conductivity type semiconductor region 120 is placed adjacent to the MISFET whose number of gate electrodes is four. The first conductivity type semiconductor region 120 is a substrate potential diffusion layer for the first conductivity type semiconductor substrate 101 as the substrate of the MISFET. The source electrodes of the MISFET are connected to the first conductivity type semiconductor region 120 as the substrate potential diffusion layer through by using the upper layer metal interconnections 119.

[Patent Document 1] Japanese Patent Publication JP-H09-275193

[Patent Document 2] Japanese Patent Publication JP-2008-251763

[Patent Document 3] Japanese Patent Publication JP-2006-295130

The inventors of the present application have recognized the following points. According to the related technique described in the Patent Documents 1 to 3, parasitic capacitance between the plugs (contacts) respectively connected to the source diffusion layer and the drain diffusion layer is not taken into consideration. Since the parasitic capacitance between the source/drain plugs is not taken into consideration, it is not possible to concurrently reduce the contact (plug) resistance and the parasitic capacitance between the source/drain contacts (plugs).

### SUMMARY

In an aspect of the present invention, semiconductor integrated circuit device is provided. The semiconductor integrated circuit device has: a MISFET having a source diffusion layer and a drain diffusion layer; first plugs connected to the source diffusion layer and the drain diffusion layer, respectively; a first interconnection connected to one of the source diffusion layer and the drain diffusion layer through the first plug; a second plug electrically connected to the other of the source diffusion layer and the drain diffusion layer through the first plug; a second interconnection connected to the second plug; and a capacitor electrode or a data memory section at least a part of which is located above a gate electrode of the MISFET. The first interconnection is formed in an interconnect layer that is formed in a same process as or before a process of a lower electrode of the part of the capacitor electrode or the data memory section. The second interconnection is formed in an interconnect layer that is located above an upper electrode of the part of the capacitor or the data memory section. A plug connecting the first interconnection and another interconnection is not provided at an upper location of a region of the one of the source diffusion layer and the drain diffusion layer. An interconnection formed in a same process as that of the first interconnection is not provided at an upper location of a region of the other of the source diffusion layer and the drain diffusion layer.

In another aspect of the present invention, a semiconductor integrated circuit device is provided. The semiconductor integrated circuit device has: a memory cell array region having a plurality of memory cells; and a logic circuit region. The memory cell array region has: a MISFET for memory cell; and a part of a capacitor electrode or a data memory section that is provided above a gate electrode of the MISFET for memory cell and has an upper node and a lower node. The logic circuit region has a MISFET having a gate electrode, a source/drain diffusion layer and a drain/source diffusion layer; a first lower layer plug electrically connected to the source/drain diffusion layer; a second lower layer plug electrically connected to the drain/source diffusion layer; an upper layer plug provided above the first lower layer plug and the second lower layer plug; a first interconnection provided in an interconnect layer below the lower node; and a second interconnection provided in an interconnect layer above the upper node. The first interconnection is electrically connected to the source/drain diffusion layer through the first lower layer plug. The second interconnection is electrically connected to the second lower layer plug through the upper layer plug. The upper layer plug is not provided at an upper location of a region of the source/drain diffusion layer. The first interconnection is not provided at an upper location of a region of the drain/source diffusion layer,

According to the present invention, the upper layer plug (second plug) is not formed at an upper location of either one of the source/drain diffusion layers. Only the lower layer plugs (first plugs) face between the source/drain sides. Due to this configuration, a facing area of the source/drain contacts (plugs) can be reduced, and thus the parasitic capacitance between the source/drain contacts (plugs) can be reduced.

Moreover, an interconnection of the same process as the first interconnection is not provided at an upper location of the other of the source/drain diffusion layers. The other of the source/drain diffusion layers is connected through the second plug to the second interconnection located above the capacitor or the data memory section. Due to this configuration, an interval between source/drain interconnections can be increased, and thus the parasitic capacitance between the source/drain contacts (plugs) can be reduced.

Furthermore, the first interconnection connected to the lower layer plug (first plug) exists in the region of the one of the source/drain diffusion layers, and a plug connecting the first interconnection and another interconnection does not exist at an upper location of the one of the source/drain diffusion layers. It is therefore possible to increase flexibility of interconnect design at the upper location.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view showing a memory cell section and a peripheral MISFET region of a semiconductor integrated circuit device according to a related technique;

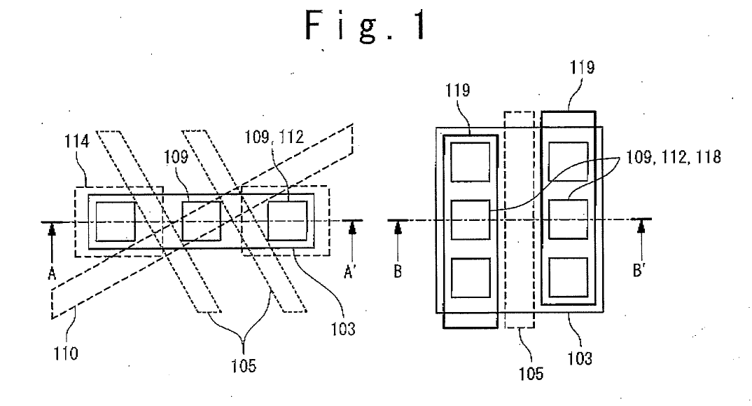

FIG. 2 is a cross-sectional view of the semiconductor integrated circuit device according to the related technique;

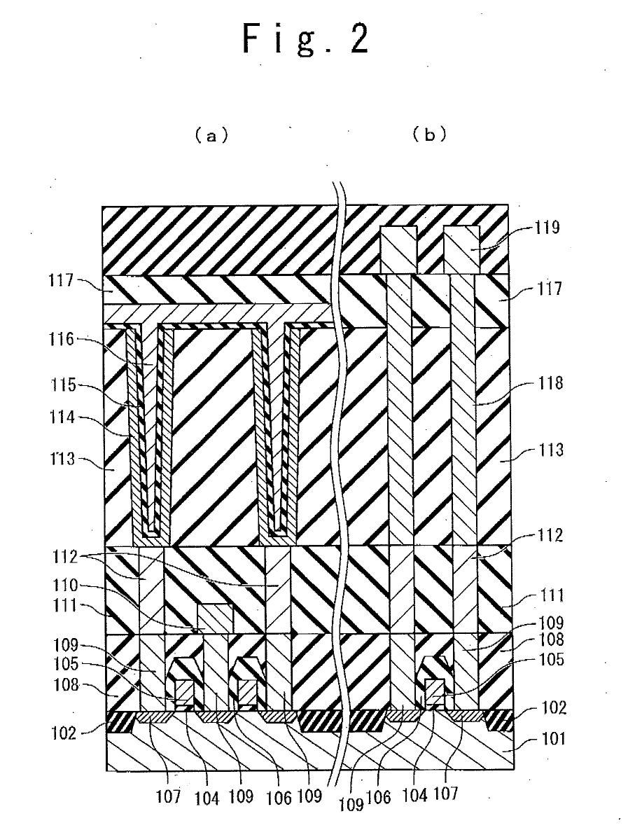

FIG. 3 is a plan view showing the peripheral MISFET region of the semiconductor integrated circuit device according to the related technique;

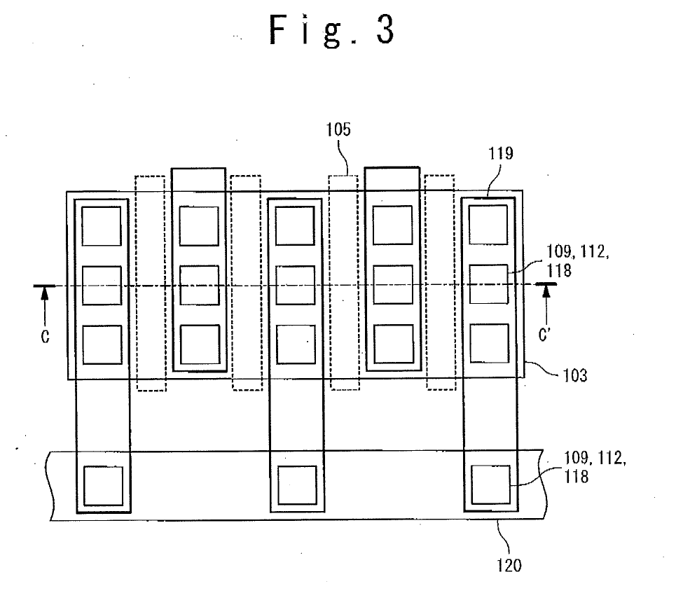

FIG. 4 is a cross-sectional view showing the peripheral MISFET region of the semiconductor integrated circuit device according to the related technique;

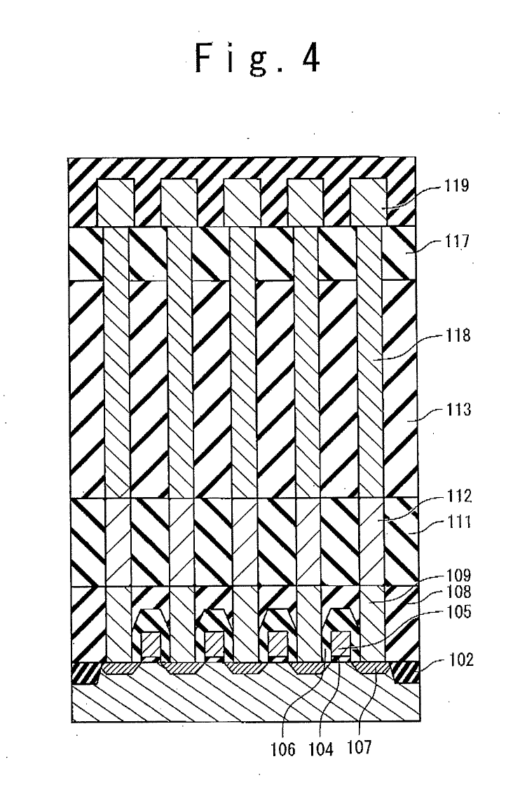

FIG. 5 is a plan view showing a configuration example of a memory cell section and a peripheral MISFET region of a semiconductor integrated circuit device according to a first embodiment of the present invention;

FIG. 6 is a cross-sectional view showing a structure example of the semiconductor integrated circuit device according to the first embodiment;

FIG. 7 is a plan view showing a configuration example of the peripheral MISFET region of the semiconductor integrated circuit device according to the first embodiment;

FIG. 8 is a cross-sectional view showing a structure example of the peripheral MISFET region of the semiconductor integrated circuit device according to the first embodiment;

FIG. 9 is a plan view showing a configuration example of a memory cell section and a peripheral MISFET region of a semiconductor integrated circuit device according to a second embodiment of the present invention;

FIG. 10 is a cross-sectional view showing a structure example of the semiconductor integrated circuit device according to the second embodiment;

FIG. 11 is a plan view showing a configuration example of a memory cell section and a peripheral MISFET region of a semiconductor integrated circuit device according to a third embodiment of the present invention;

FIG. 12 is a cross-sectional view showing a structure example of the semiconductor integrated circuit device according to the third embodiment;

FIG. 13 is a plan view showing a configuration example of the peripheral MISFET region of the semiconductor integrated circuit device according to the third embodiment;

FIG. 14 is a cross-sectional view showing a structure example of the peripheral MISFET region of the semiconductor integrated circuit device according to the third embodiment;

FIG. 15 shows a mask layout of a two-stage inverter circuit according to a reference example;

FIG. 16 is a schematic plan view showing a chip having a logic circuit section including the inverter circuit according to the reference example and a memory cell array section;

FIG. 17 shows a mask layout of a two-stage inverter circuit according to the present embodiment; and

FIG. 18 is a schematic plan view showing a chip having a logic circuit section including the inverter circuit according to the present embodiment example and a memory cell array section.

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Embodiments of the present invention will be described below with reference to the attached drawings. It should be noted that the same reference numerals are basically given to the same components, and an overlapping description will be omitted as appropriate. In the embodiments described below, a case where a semiconductor integrated circuit device is a memory embedded logic IC having a memory cell section and a peripheral MISFET region (logic circuit section) will be described as an example.

### First Embodiment

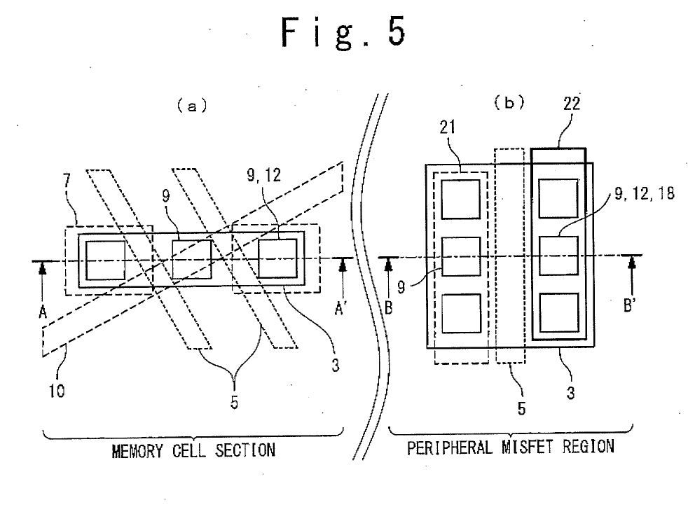

FIG. 5 is a plan view showing a configuration example of the semiconductor integrated circuit device according to a first embodiment of the present invention. The semiconductor integrated circuit device according to the first embodiment has a memory cell section and a peripheral MISFET region (logic circuit section). The (a) part of FIG. 5 shows a configuration example of the memory cell section when viewed from the above. The (b) part of FIG. 5 shows a configuration example of the peripheral MISFET region (logic circuit section) when viewed from the above. The memory cell section has a plurality of memory cells. The peripheral MISFET region (logic circuit section) has a plurality of MISFETs.

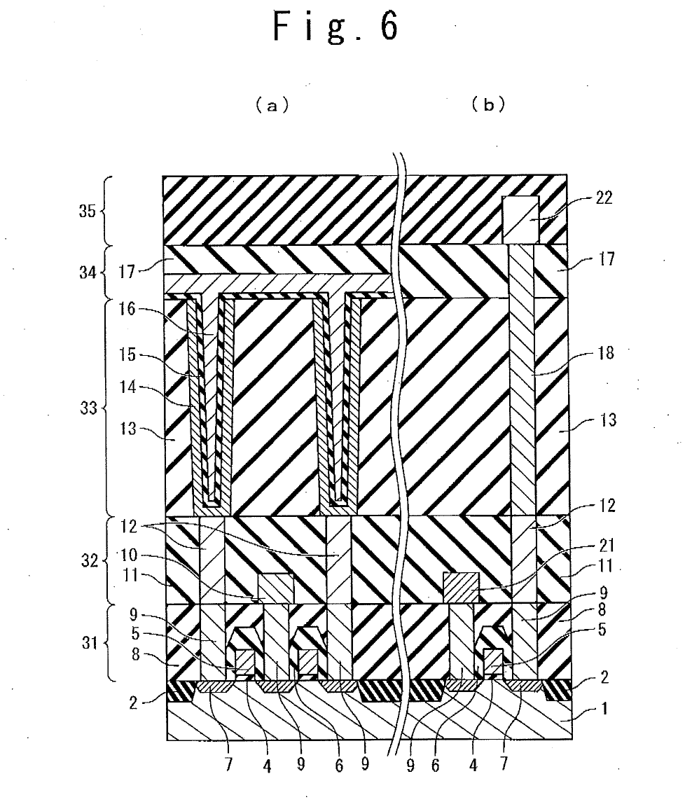

FIG. 6 is a cross-sectional view showing a cross-sectional structure example of the memory cell section and the peripheral MISFET region (logic circuit section) of the semiconductor integrated circuit device according to the first embodiment. The (a) part of FIG. 6 shows a cross-sectional structure taken along a line A-A′ in FIG. 5. The (b) part of FIG. 6 shows a cross-sectional structure taken along a line B-B′ in FIG, 5.

As shown in FIG. 6, the semiconductor integrated circuit device according to the present embodiment has multi interconnect layers. The multi interconnect layers include a first interlayer insulating film formation layer 31, a second interlayer insulating film formation layer 32, a third interlayer insulating film formation layer 33, a fourth interlayer insulating film formation layer 34 and a fifth interlayer insulating film formation layer 35. In the first interlayer insulating film formation layer 31, first contacts 9 are so formed as to penetrate through a first interlayer insulating film 8. In the second interlayer insulating film formation layer 32, second contacts 12 penetrating through a second interlayer insulating film 11, a bit line 10 and a first interconnection 21 are formed. In the third interlayer insulating film formation layer 33, third contacts 18 penetrating through a third interlayer insulating film 13 and components of a capacitor element (a first capacitor electrode 14, a capacitor insulating film 15 and a second capacitor electrode 16) are formed. In the fourth interlayer insulating film formation layer 34, contacts penetrating through a fourth interlayer insulating film 17 and an interconnection connected to the second capacitor electrode 16 are formed. In the fifth interlayer insulating film formation layer 35, a second interconnection 22 is formed.

As shown in FIG. 5 and FIG. 6, one of source/drain electrodes of the MISFET is connected to the first interconnection 21 through the first contact 9, in the peripheral MISFET region (logic circuit section) of the semiconductor integrated circuit device according to the present embodiment. Meanwhile, the other of source/drain electrodes is connected to the second interconnection 22 through the first contact 9, the second contact 12 and the third contact 18. Here, the first interconnection 21 is not formed in the second interlayer insulating film formation layer 32 at an upper location of the first contact 9 connected to the other of source/drain electrodes. The first contact 9 connected to the other of source/drain electrodes is directly connected to the stacked second contact 12 without through the first interconnection 21.

Next, a manufacturing process of the semiconductor integrated circuit device according to the present embodiment will be described. In the manufacturing process, a device isolation film 2 and a device formation region (diffusion layer region) 3 are formed at predetermined locations of a first conductivity type semiconductor substrate 1. Then, a gate electrode 5 is formed on a channel region of the MISFET through a gate insulating film 4. A side wall insulating film 6 is so formed as to cover around the gate electrode 5. Next, impurity ions are doped and then heat treatment is performed to form second conductivity type semiconductor regions 7 as the source/drain diffusion layers in the device formation region 3.

After that, the first interlayer insulating film 8 is formed on the entire surface in the first interlayer insulating film formation layer 31. Then, the first contacts 9 are formed at predetermined locations in the first interlayer insulating film 8. Then, a bit line 10 connected to the first contact 9 is formed in the memory cell section. At this time, by the same process as for forming the bit line 10, the first interconnection 21 connected to the first contact 9 is formed in the peripheral MISFET region (logic circuit section).

After that, the second interlayer insulating film 11 is formed on the entire surface in the second interlayer insulating film formation layer 32. Then, the second contacts 12 are so formed at corresponding locations of the first contacts 9 as to be directly connected to the respective first contacts 9. Then, the third interlayer insulating film 13 is formed on the entire surface in the third interlayer insulating film formation layer 33. The first capacitor electrode 14 of a memory cell is formed at a predetermined location in the third interlayer insulating film 13. After that, the capacitor insulating film 15 and a metal layer are blanket deposited and then the second capacitor electrode 16 is formed.

After that, the fourth interlayer insulating film 17 is formed on the entire surface in the fourth interlayer insulating film formation layer 34. Then, the third contacts 18 are so formed at corresponding locations of the second contacts 12 as to be directly connected to the respective second contacts 12. Then, the second interconnection 22 connected to the third contact 18 is formed. It should be noted that the third contact 18 may be formed through a process of etching the third interlayer insulating film 13 and the fourth interlayer insulating film 17 at one time. Alternatively, the third contact 18 may be formed by a plurality of processes so as to separately penetrate through the third interlayer insulating film 13 and the fourth interlayer insulating film 17. Each plug (contact) may be formed of a plurality of plugs that are stacked.

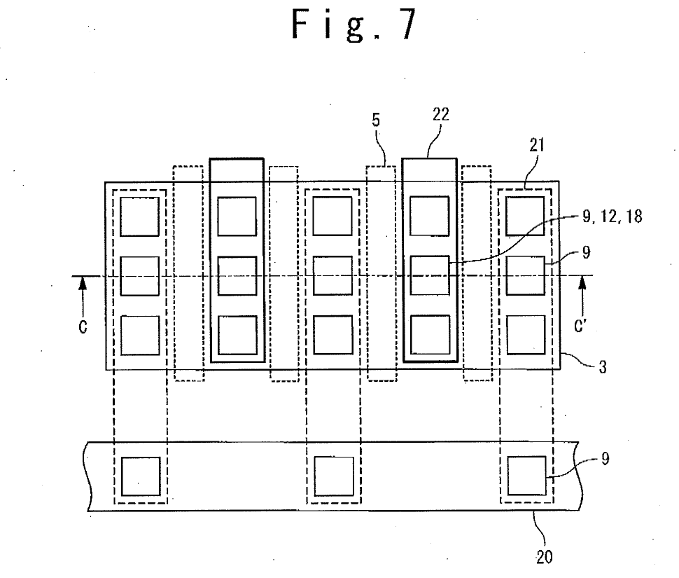

FIG. 7 is a plan view showing the peripheral MISFET region (logic circuit section) according to the first embodiment in a case where the number of gate electrodes is four. As shown in FIG. 7, a substrate potential is supplied to the source electrode of the MISFET. The source electrode is connected to a first conductivity type semiconductor region 20 that is a diffusion layer for supplying the substrate potential. In the semiconductor integrated circuit device according to the first embodiment, the first conductivity type semiconductor region 20 is placed adjacent to the peripheral MISFET region (logic circuit section) where the number of gate electrodes is four. By using the first interconnection 21, the source electrodes of the MISFET are extended in a direction parallel to the gate electrode of the MISFET to be connected to the first conductivity type semiconductor region 20 as the substrate potential diffusion layer.

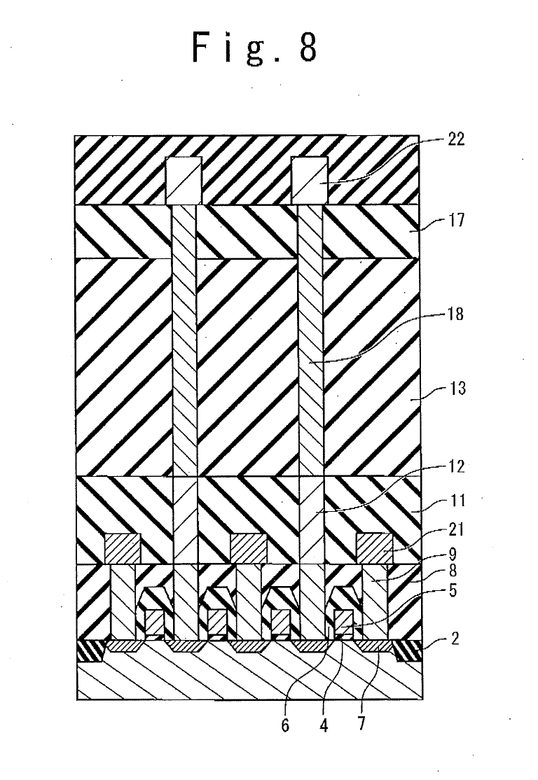

FIG. 8 is a cross-sectional view showing a cross-sectional structure example of the peripheral MISFET region (logic circuit section) where the number of gate electrodes is four in the first embodiment. FIG. 8 is a cross-sectional view taken along a line C-C′ in FIG. 7. As shown in FIG. 8, one of the source/drain electrodes of the MISFET is connected to the first interconnection 21 through the first contact 9. Moreover, the first interconnection 21 is not provided at an upper location of a region of the other of the source/drain electrodes. The other of the source/drain electrodes is connected to the second interconnection 22 through the first contact 9, the second contact 12 and the third contact 18.

Due to this configuration, it is possible to increase an interval between the source/drain interconnections and to reduce a facing area of the source/drain plugs (contacts). As a result, the parasitic capacitance between the source/drain plugs (contacts) can be reduced. Moreover, the first interconnection 21 is formed by the same process as that for forming the bit line 10. Thus, the semiconductor integrated circuit device according to the present embodiment can be achieved without increasing the number of processes.

### Second Embodiment

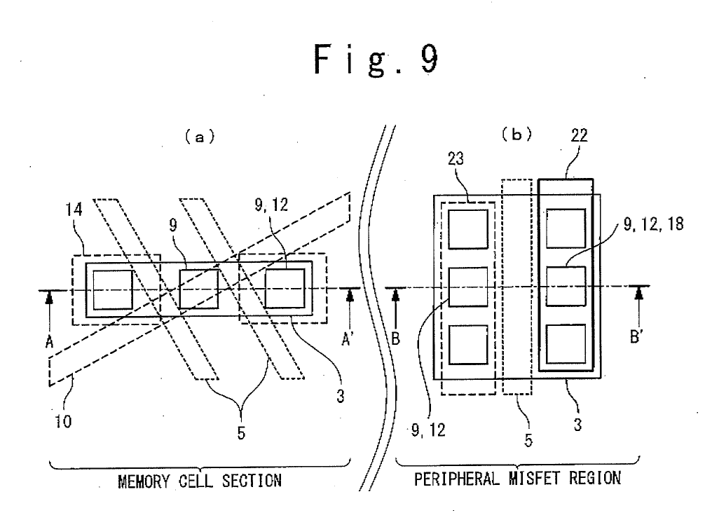

Next, a second embodiment of the present invention will be described. FIG. 9 is a plan view showing a configuration example of the semiconductor integrated circuit device according to the second embodiment of the present invention. The semiconductor integrated circuit device according to the second embodiment has the memory cell section and the peripheral MISFET region (logic circuit section). The (a) part of FIG. 9 shows a configuration example of the memory cell section when viewed from the above. The (b) part of FIG. 9 shows a configuration example of the peripheral MISFET region (logic circuit section) when viewed from the above. The memory cell section has a plurality of memory cells. The peripheral MISFET region (logic circuit section) has a plurality of MISFETs. As shown in FIG. 9, the semiconductor integrated circuit device according to the second embodiment has a third interconnection 23.

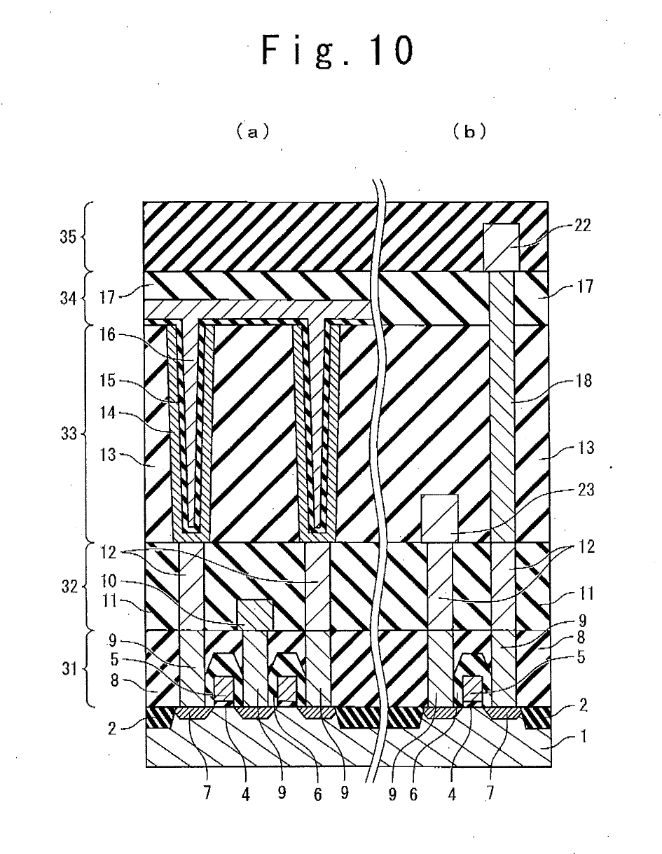

FIG. 10 is a cross-sectional view showing a cross-sectional structure example of the memory cell section and the peripheral MISFET region (logic circuit section) of the semiconductor integrated circuit device according to the second embodiment. The (a) part of FIG. 10 shows a cross-sectional structure taken along a line A-A′ in FIG. 9. The (b) part of FIG. 10 shows a cross-sectional structure taken along a line B-B′ in FIG. 9.

In the peripheral MISFET region (logic circuit section), one of source/drain electrodes of the MISFET is connected to the third interconnection 23 through the first contact 9 and the second contact 12. Meanwhile, the other of source/drain electrodes is connected to the second interconnection 22 through the first contact 9, the second contact 12 and the third contact 18. Here, the second contact 12 connected to the other of source/drain electrodes through the first contact 9 is directly connected to the stacked third contact 18 without through the third interconnection 23.

Next, a manufacturing process of the semiconductor integrated circuit device according to the second embodiment will be described. The manufacturing process in the second embodiment is the same as the manufacturing process in the first embodiment described in FIGS. 5 and 6 up to a point where the first contacts 9 are formed. According to the second embodiment, after the first contacts 9 are formed, a bit line 10 connected to the first contact 9 is formed in the memory cell section. After that, the second interlayer insulating film 11 is formed on the entire surface. Then, the second contacts 12 are so formed at corresponding locations of the first contacts 9 as to he directly connected to the respective first contacts 9.

After that, in the peripheral MISFET region (logic circuit section), the third interconnection 23 connected to the second contact 12 is formed on the second interlayer insulating film 11 of the second interlayer insulating film formation layer 32. Then, the third interlayer insulating film 13 is formed on the entire surface in the third interlayer insulating film formation layer 33. The process from the formation of the third interlayer insulating film 13 to the formation of the second interconnection 22 is the same as in the case of the first embodiment.

In the second embodiment, one of source/drain electrodes of the MISFET is connected to the third interconnection 23 through the first contact 9 and the second contact 12. Meanwhile, the other of source/drain electrodes is connected to the second interconnection 22 through the first contact 9, the second contact 12 and the third contact 18. The third interconnection 23 in the second embodiment is formed by a process different from a process for forming the bit line 10. Thus, a lower-resistance interconnect material as compared with material of the bit line 10 can be used for forming the third interconnection 23.

### Third Embodiment

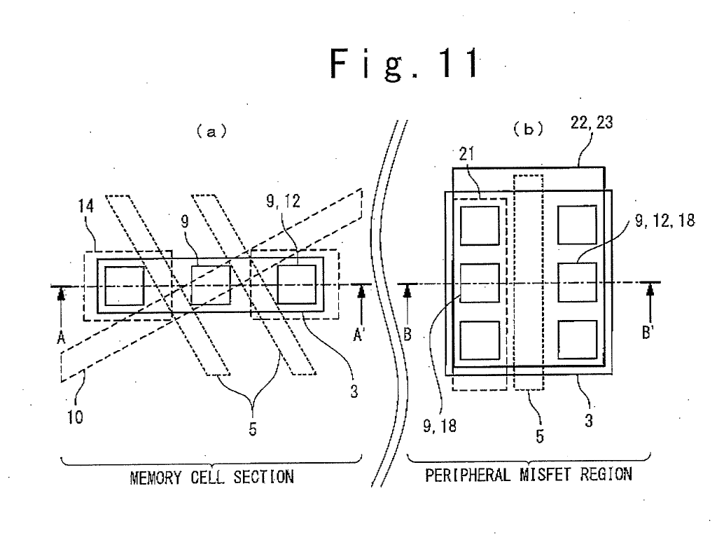

Next, a third embodiment of the present invention will be described. FIG. 11 is a plan view showing a configuration example of the semiconductor integrated circuit device according to the third embodiment of the present invention. The semiconductor integrated circuit device according to the third embodiment has the memory cell section and the peripheral MISFET region (logic circuit section). The (a) part of FIG. 11 shows a configuration example of the memory cell section when viewed from the above. The (b) part of FIG. 11 shows a configuration example of the peripheral MISFET region (logic circuit section) when viewed from the above. The memory cell section has a plurality of memory cells. The peripheral MISFET region (logic circuit section) has a plurality of MISFETs. As shown in FIG. 11, the semiconductor integrated circuit device according to the third embodiment has a second interconnection 22 and a third interconnection 23 whose shapes are different from those in the above-described embodiment.

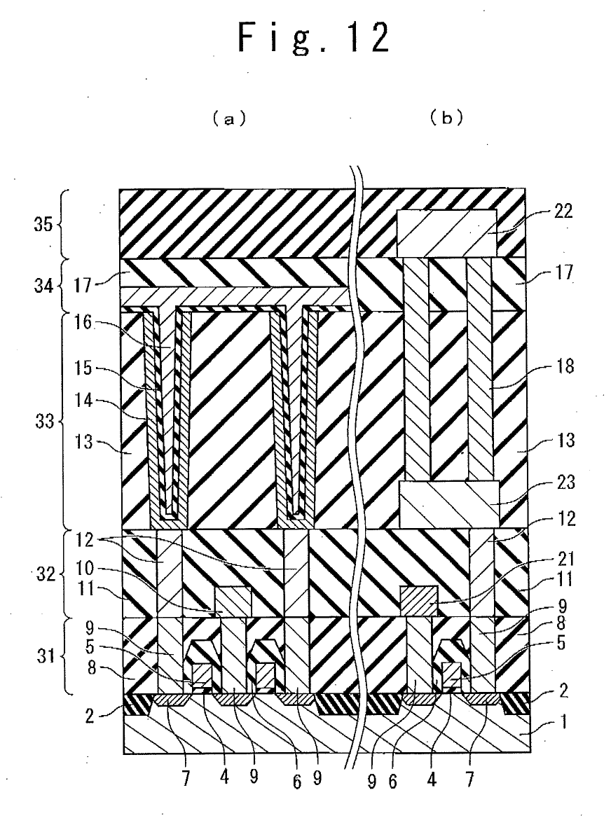

FIG. 12 is a cross-sectional view showing a cross-sectional structure example of the semiconductor integrated circuit device according to the third embodiment. The (a) part of FIG, 12 shows a cross-sectional structure taken along a line A-A′ in FIG. 11. The (b) part of FIG. 12 shows a cross-sectional structure taken along a line B-B′ in FIG. 11.

According to the third embodiment, in the peripheral MISFET region (logic circuit section), one of source/drain electrodes of the MISFET is connected to the first interconnection 21 through the first contact 9. Meanwhile, the other of source/drain electrodes is connected to the second interconnection 22 through the third contact 18.

In the semiconductor integrated circuit device according to the third embodiment, the first interconnection 21 is not provided at an upper location of the first contact 9 connected to the other of source/drain electrodes. Moreover, the first contact 9 connected to the other of source/drain electrodes is electrically connected to the second interconnection 22 through the third contacts 18 formed in the third interlayer insulating film formation layer 33 and the third interconnection 23 formed below the third contacts 18.

Next, a manufacturing process of the semiconductor, integrated circuit device according to the third embodiment will be described. The manufacturing process of the semiconductor integrated circuit device in the third embodiment is the same as the manufacturing process in the first embodiment up to a point where the second contacts 12 are formed. After the second contacts 12 are formed, the third interconnection 23 connected to a second contact 12 is formed in the peripheral MISFET region. The process from the formation of the third interlayer insulating film 13 to the formation of the fourth interlayer insulating film 17 is the same as in the case of the first embodiment.

After the fourth interlayer insulating film 17 is formed, the third contacts 18 connected to the above-mentioned third interconnection 23 are formed. In the semiconductor integrated circuit device according to the third embodiment, the third contacts 18 are connected to the second contact 12 through the third interconnection 23. Therefore, there is no need to form a contact hole at a position corresponding to the second contact 12 or the first contact 9, in the manufacturing process of the third contact 18. After the formation of the third contact 18 is completed, the second interconnection 22 connected to the third contact 18 is formed.

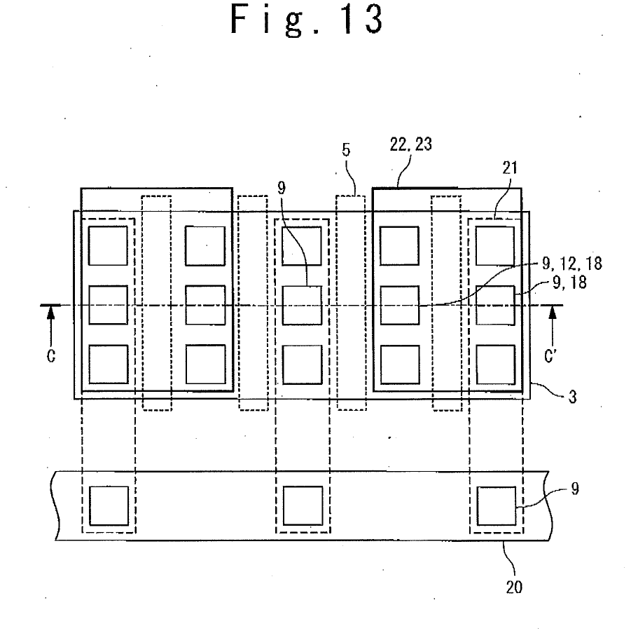

FIG. 13 is a plan view showing a configuration example of the peripheral MISFET region of the semiconductor integrated circuit device according to the third embodiment. FIG. 13 shows a configuration example of the peripheral MISFET region where the number of gate electrodes is four. In the device, the source electrode is connected to an electrode for supplying a substrate potential.

In the semiconductor integrated circuit device, as shown in FIG. 13, a first conductivity type semiconductor region 20 is placed adjacent to the peripheral MISFET region (logic circuit section) where the number of gate electrodes is four. As in the case of the first embodiment, by using the first interconnection 21, the source electrodes of the MISFET are extended in a direction parallel to the gate electrode of the MISFET to be connected to the first conductivity type semiconductor region 20 as the substrate potential diffusion layer.

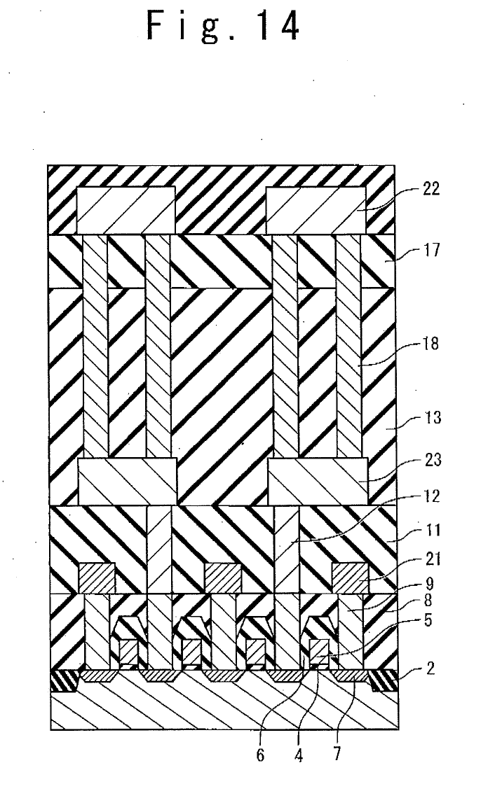

FIG. 14 is a cross-sectional view showing a cross-sectional structure example of the peripheral MISFET region (logic circuit section) of the semiconductor integrated circuit device according to the third embodiment. FIG. 14 is a cross-sectional view taken along a line C-C′ in FIG. 13. As shown in FIG. 14, the drain electrodes of the MISFET are connected to the third interconnection 23 through the second contact 12. Moreover, the third interconnection 23 is connected to the second interconnection 22 through the third contacts 18.

In the third embodiment, the second interconnection 22 is connected to the third interconnection 23 through the plurality of third contacts 18. Therefore, the interconnect resistance can be reduced as compared with the case of the first embodiment. It should be noted that the interconnect width of the second interconnection 22 at the upper location of the MISFET can be increased not only in the third embodiment but also in the first embodiment and the second embodiment. In this case, the interconnect resistance can be reduced as in the case of the third embodiment. In particular, when the second interconnection 22 is a power supply/ground interconnection (MISFET source potential electrode), the resistance of the source interconnection can be reduced by increasing the interconnect width, which is preferable.

### REFERENCE EXAMPLE

In the above-described embodiments, which of the two source/drain electrodes of the MISFET is connected to the upper layer interconnection is not specified. To facilitate understanding of the present embodiment, a case where the source electrode of the MISFET is connected to the upper layer interconnection will be exemplified below.

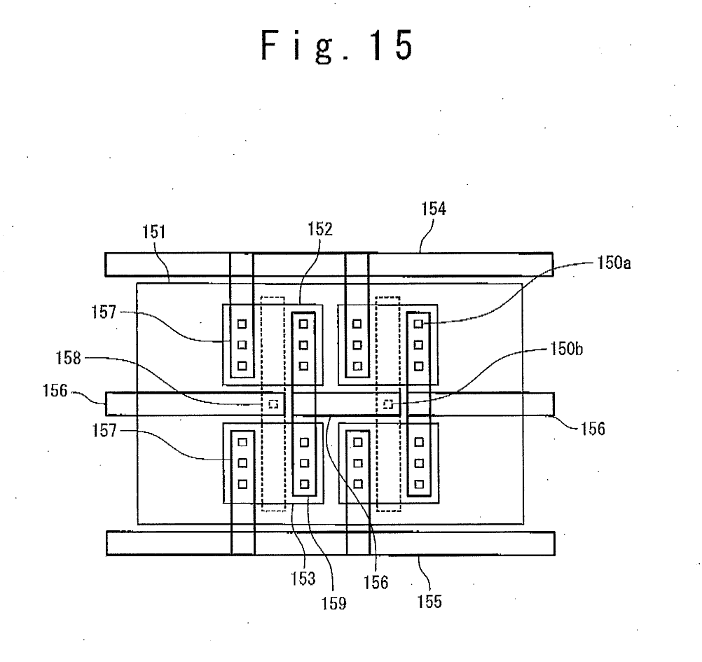

First, a reference example will be explained. FIG. 15 shows an example of a mask layout of a two-stage inverter circuit according to the reference example to which the present invention is not applied. As shown in FIG. 15, an inverter circuit block. 151 has a P-channel MISFET (P-MISFET) 152 and a N-channel MISFET (N-MISFET) 153. A gate interconnection 158 of the P-MISFET 152 and the N-MISFET 153 is connected to a signal interconnection 156 through a plug 150b. A signal voltage is supplied to the gate interconnection 158 through the signal interconnection 156.

A source electrode of the P-MISFET 152 is connected to a source interconnection 157 through a plug 150a. The source interconnection 157 on the side of the P-MISFET 152 is connected to a power supply interconnection 154 that is an upper layer interconnection. A source electrode of the N-MISFET 153 is connected to a source interconnection 157 through a plug 150a. The source interconnection 157 on the side of the N-MISFET 153 is connected to a GND interconnection 155 that is an upper layer interconnection. Moreover, a drain electrode is connected to a drain interconnection 159 through a plug 150a. The drain interconnection 159 is connected to an upper layer interconnection (signal interconnection 156).

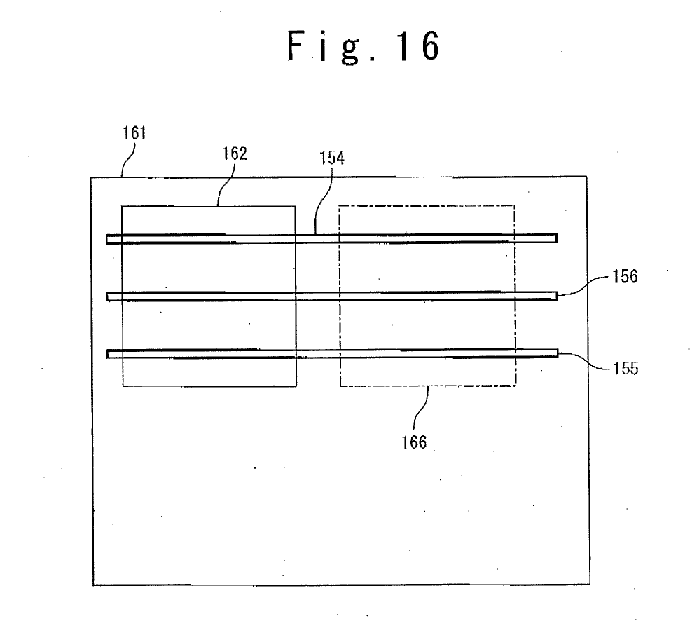

Here, a schematic layout of a chip of the semiconductor integrated circuit device including the inverter circuit to which the present invention is not applied will be described. FIG. 16 is a plan view showing a configuration example of the chip. 161 provided with a logic circuit section 166 including the two-stage inverter circuit and a memory cell array section 162.

The power supply interconnection 154 and the GND interconnection 155 are laid-out so as to cross the chip. When the interconnect widths of the power supply interconnection 154 and the GND interconnection 155 are desired to be increased, the interconnect widths of the power supply interconnection 154 and the GND interconnection 155 need to be increased outward of the inverter circuit block 151. As a result, an area of the chip is increased.

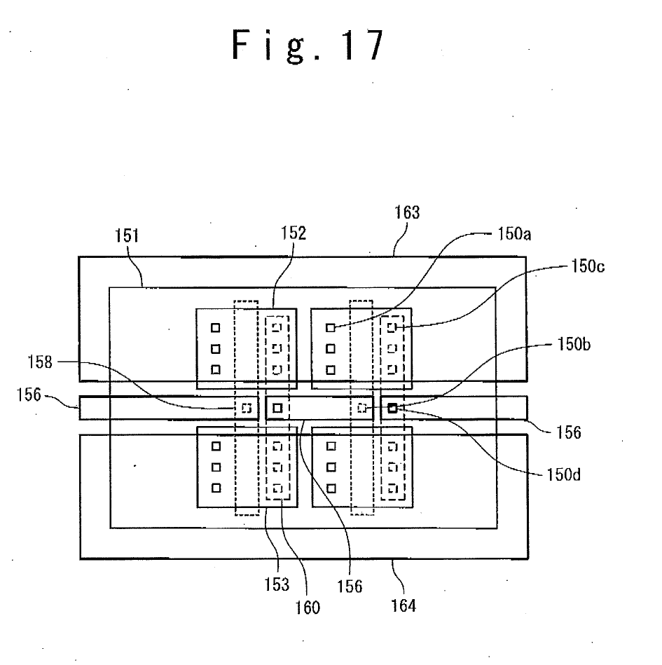

Next, the semiconductor integrated circuit device to which the present invention is applied will be described. FIG. 17 shows a layout example of a two-stage inverter circuit to which the present invention is applied. In the layout, the source electrode of the two-stage inverter circuit is connected to the upper layer interconnection, and the drain electrode thereof is connected to the lower layer interconnection.

As shown in FIG. 17, the source electrode of the P-MISFET 152 is connected through the second plug comprised of the plug 150a to a power supply interconnection 163 that is an upper layer interconnection (second interconnect layer). Similarly, the source electrode of the N-MISFET 153 is connected through the second plug comprised of the plug 150a to a GND interconnection 164 that is an upper layer interconnection (second interconnect layer).

The drain electrode of the P-MISFET 152 is connected through the first plug comprised of a plug 150c to a drain interconnection 160 that is a lower layer interconnection (first interconnect layer). Similarly, the drain electrode of the N-MISFET 153 is connected through the first plug comprised of a plug 150c to a drain interconnection 160 that is a lower layer interconnection (first interconnect layer).

The drain interconnection 160 extends in a direction parallel to the gate electrode of the MISFET. Moreover, the drain electrode is connected through the third plug comprised of a plug 150d to the signal interconnection 156 as the upper layer interconnection (second interconnect layer), at a location other than the upper location of the region of the drain diffusion layer. It should be noted that the drain interconnection 160 needs not be connected to the upper layer interconnection (signal interconnection 156) within the inverter circuit block. When the drain interconnection 160 is drawn out to the outside of the inverter circuit block, it is connected to an upper layer interconnection as in the cases of the above-described embodiments.

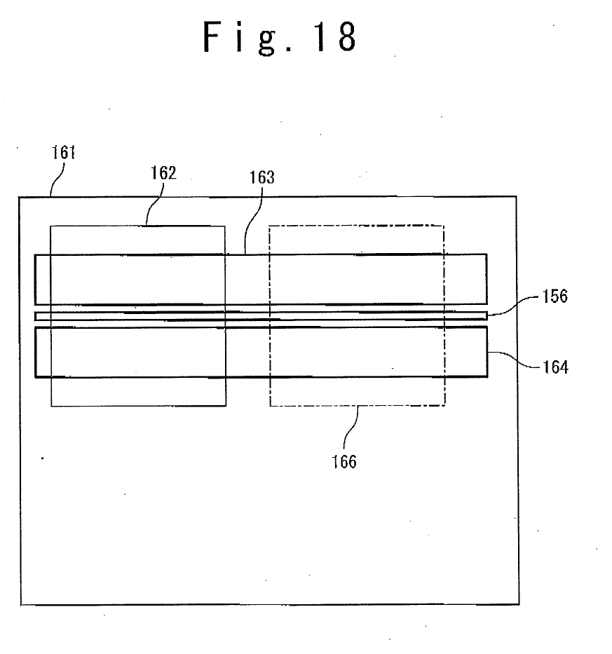

FIG. 18 is a plan view showing a configuration example of the chip provided with the logic circuit section including the inverter circuit whose configuration is as shown in FIG. 17 and the memory cell array section. As shown in the plan view, the layout in the present embodiment makes it possible to suppress increase in the chip area and to increase the interconnect widths of the power supply interconnection 163 and the GND interconnection 164.

Described in the first to third embodiments are the cases where the present invention is applied to a memory such as a DRAM and a FeRAM having a stack type capacitor as a data memory section. The present invention can be also applied to a memory such as an MRAM having a magnetoresistance element as a data memory section. Even in this case, the same effects as in the first to third embodiments can be obtained.

Described in the first to third embodiments are cases where the first conductivity type semiconductor region 1, the gate insulating film 4, the gate electrode 5, the side wall insulating film 6 and the second conductivity type semiconductor region 7 are the same between the memory cell section and the peripheral MISFET region. However, the semiconductor conductivity type, type and concentration of semiconductor impurities, type and a thickness of the insulating film, type and a thickness of the conductive film may be different between the memory cell section and the peripheral MISFET region.

Described in the first to third embodiments are cases where the source/drain electrodes of the MISFET are diffusion layers or semiconductor regions. However, the diffusion layers or the semiconductor regions as the source/drain electrodes may be silicided in order to obtain excellent electric conduction.

Described in the first to third embodiments are cases where the first interconnection extends in a direction parallel to the gate electrode of the MISFET. However, the first interconnection may extend in a direction perpendicular to the gate electrode of the MISFET in order to reduce the parasitic capacitance or to reduce the layout area.

Described in the first to third embodiments are cases where the interconnection is formed on the interlayer insulating film. However, the interconnection may be formed by providing the interlayer insulating film with a trench and filling the trench with conductive material. Moreover, the interconnection and the contact (plug) may be formed by different processes or may be formed by the same process. Furthermore, each plug may be formed of a plurality of plugs that are stacked.

It is apparent that the present invention is not limited to the above embodiments and may be modified and changed without departing from the scope and spirit of the invention.

It is apparent that the present invention is not limited to the above embodiments and may be modified and changed without departing from the scope and spirit of the invention.

What is claimed is:

1. A semiconductor integrated circuit device comprising:
a MISFET having a source diffusion layer and a drain diffusion layer;
first plugs connected to said source diffusion layer and said drain diffusion layer, respectively;
a first interconnection connected to one of said source diffusion layer and said drain diffusion layer through said first plug;
a second plug electrically connected to the other of said source diffusion layer and said drain diffusion layer through said first plug;
a second interconnection connected to said second plug; and
a capacitor electrode or a data memory section at least a part of which is located above a gate electrode of said MISFET,
wherein said first interconnection is formed in an interconnect layer that is formed in a same process as or before a process of a lower electrode of said part of said capacitor electrode or said data memory section, and
said second interconnection is formed in an interconnect layer that is located above an upper electrode of said part of said capacitor or said data memory section,
wherein a plug connecting said first interconnection and another interconnection is not provided at an upper location of a region of said one of said source diffusion layer and said drain diffusion layer, and
an interconnection formed in a same process as that of said first interconnection is not provided at an upper location of a region of said other of said source diffusion layer and said drain diffusion layer.

2. The semiconductor integrated circuit device according to claim 1,
wherein said second plug is directly connected to said first plug.

3. The semiconductor integrated circuit device according to claim 1,
wherein said second plug is electrically connected to said first plug through another conductive material.

4. The semiconductor integrated circuit device according to claim 1,
wherein said first interconnection extends in a direction parallel to or perpendicular to said gate electrode of said MISFET.

5. The semiconductor integrated circuit device according to claim 1,
wherein at least one of said source diffusion layer and said drain diffusion layer is silicided.

6. The semiconductor integrated circuit device according to claim 1,
wherein said first interconnection is connected through a third plug to an interconnect layer formed in a same process as that of said second interconnection, at a location other than said upper location of said region of said one of said source diffusion layer and said drain diffusion layer.

7. The semiconductor integrated circuit device according to claim 1,
wherein said first plug is formed of a plurality of plugs that are stacked.

8. The semiconductor integrated circuit device according to claim 1,
wherein said second plug is formed of a plurality of plugs that are stacked.

9. The semiconductor integrated circuit device according to claim 6,
wherein said third plug is formed of a plurality of plugs that are stacked.

10. A semiconductor integrated circuit device comprising:
a memory cell array region having a plurality of memory cells; and
a logic circuit region,
wherein said memory cell array region comprises:
a MISFET for memory cell; and
a part of a capacitor electrode or a data memory section that is provided above a gate electrode of said MISFET for memory cell and has an upper node and a lower node,
wherein said logic circuit region comprises:
a MISFET having a gate electrode, a source/drain diffusion layer and a drain/source diffusion layer;
a first lower layer plug electrically connected to said source/drain diffusion layer;
a second lower layer plug electrically connected to said drain/source diffusion layer;
an upper layer plug provided above said first lower layer plug and said second lower layer plug;
a first interconnection provided in an interconnect layer below said lower node; and
a second interconnection provided in an interconnect layer above said upper node,
wherein said first interconnection is electrically connected to said source/drain diffusion layer through said first lower layer plug,
said second interconnection is electrically connected to said second lower layer plug through said upper layer plug,
said upper layer plug is not provided at an upper location of a region of said source/drain diffusion layer, and
said first interconnection is not provided at an upper location of a region of said drain/source diffusion layer.

11. The semiconductor integrated circuit device according to claim 10,
wherein said first interconnection is provided at least at an upper location of said source/drain diffusion layer, and
said second interconnection is provided at least at an upper location of said drain/source diffusion layer.

12. The semiconductor integrated circuit device according to claim 10,
wherein at the upper location of said source/drain diffusion layer, said first interconnection is formed without being in contact with a plug connecting said first interconnection and another interconnection.
